(19) United States
(12) Patent Application Publication
(10) Pub. No.: US 2017/0296982 A1
(43) Pub. Date: Oct. 19, 2017

(54) HEALING OF THIN GRAPHENIC-BASED MEMBRANES VIA CHARGED PARTICLE IRRADIATION

(71) Applicant: Lockheed Martin Corporation, Bethesda, MD (US)

(72) Inventors: Jacob Louis Swett, Redwood City, CA (US); Peter V. Bedworth, Los Gatos, CA (US)

(73) Assignee: Lockheed Martin Corporation, Bethesda, MD (US)

(21) Appl. No.: 15/099,447

(22) Filed: Apr. 14, 2016

(51) Int. Cl. B01D 71/02; C23C 16/26; B01D 67/00; C23C 16/48

(52) U.S. Cl. CPC B01D 71/021; C23C 16/48; B01D 67/0072; B01D 67/009; C23C 16/26

(57) ABSTRACT

A method of forming a membrane is described. A graphenic-based membrane is formed on a growth substrate, where the graphenic-based membrane have one or more layers of graphenic-based material. The graphenic-based membrane is removed from the growth substrate. A region of the graphenic-based membrane having intrinsic or native defects is identified. The region of the graphenic-based membrane is irradiated with charged particles while introducing carbonaceous material on a surface of the one or more layers of graphenic-based material to heal the intrinsic or native defects.

The disclosure generally relates to healing of graphenic-based membranes, such as graphene-based membranes, using charged particle irradiation.

### BACKGROUND

Graphene-based membranes can be formed by initial deposition of graphene-based material on a growth substrate. The membrane is then typically removed from the growth substrate and positioned on a support substrate. The membrane may also be formed on the functional end substrate and need not be removed.

Perforations, such as pores, may be selectively introduced into the graphene-based membrane. The graphene-based membrane with perforations of a selective size may be used as a filter, allowing one species of a smaller size to pass through the perforations, while restricting a species of a larger size from passing through the perforations. Graphene-based membranes without perforations may be used as a barrier.

These graphene-based membranes are subject to intrinsic or native defects. Intrinsic or native defects are those resulting from preparation of the graphene-based membrane in contrast to perforations which are selectively introduced into the membrane. Such intrinsic or native defects include lattice anomalies, pores, tears, cracks or wrinkles. Further, for thin graphene-based membranes and thin graphitic membranes, the intrinsic or native defects may also include regions where no graphene or graphitic material was deposited, or it was sparsely deposited.

### SUMMARY

According to one embodiment there is provided a method of forming a membrane. The method comprises: forming a graphenic-based membrane on a growth substrate, the graphenic-based membrane having one or more layers of graphenic-based material; removing the graphenic-based membrane from the growth substrate; identifying a region of the graphenic-based membrane having intrinsic or native defects; and irradiating the region of the graphenic-based membrane with charged particles while introducing carbonaceous material on a surface of the one or more layers of graphenic-based material to heal the intrinsic or native defects.

According to one aspect, the graphenic-based membrane is one of a graphene-based membrane and a graphitic-based membrane.

According to another embodiment there is provided a method of forming a membrane. The method comprises: forming a graphenic-based membrane on a growth substrate, the graphenic-based membrane having one or more layers of graphenic-based material, and carbonaceous material on a surface of the one or more layers of graphenic-based material; removing the graphenic-based membrane from the growth substrate; identifying a region of the graphenic-based membrane having intrinsic or native defects; and irradiating the region of the graphenic-based membrane with charged particles to heal the intrinsic or native defects.

According to one aspect the graphenic-based membrane is a graphene-based membrane.

According to another aspect, the method further comprises performing a conditioning treatment on the graphenic-based membrane while the graphenic-based membrane is on the growth substrate.

According to another aspect, the performing a conditioning treatment comprises an ion beam treatment of an initial graphenic-based membrane,

According to another aspect, the irradiating the region of the graphenic-based membrane with charged particles is performed after performing the conditioning treatment.

According to another aspect, the graphenic-based membrane comprises a plurality of selectively introduced perforations in addition to the intrinsic or native defects.

According to another aspect, the selectively introduced perforations have a first characteristic size, and the region includes intrinsic or native defects of a second characteristic size larger than the first characteristic size.

According to another aspect, the irradiating the region of the graphenic-based membrane with charged particles comprises: identifying the region based on the intrinsic or native defects of a second characteristic size larger than the first characteristic size; and scanning a charged particle beam over the identified region.

According to another embodiment there is provided a method of forming a membrane, The method comprises: producing a graphenic-based membrane having one or more layers of graphenic-based material, the graphenic-based membrane having intrinsic or native defects in a region; and irradiating the region of the graphenic-based membrane with charged particles while introducing carbonaceous material on a surface of the one or more layers of graphenic-based material to heal the intrinsic or native defects.

According to another aspect, the graphenic-based membrane is a graphene-based membrane.

According to another embodiment there is provided a method of forming a membrane. The method comprises: producing a graphenic-based membrane having one or more layers of graphenic-based material, and carbonaceous material on a surface of the one or more layers of graphenic-based material, the graphenic-based membrane having intrinsic or native defects in a region; and irradiating the region of the graphenic-based membrane with charged particles to heal the intrinsic or native defects.

According to one aspect, the intrinsic or native defects comprise at least one of lattice anomalies, pores, tears, cracks or wrinkles.

According to another aspect, the intrinsic or native defects comprise tears.

According to another aspect, the irradiating the region of the graphenic-based membrane comprises irradiating with charged particles having an ion energy ranging from 50 eV to 40 keV, and a flux ranging from 10¹⁰ ions/cm²/s to 10¹⁷ ions/cm²/s.

According to another aspect, the irradiating the region of the graphenic-based membrane comprises irradiating with one of a broad beam or a flood source.

According to another aspect, the producing a graphenic-based membrane comprises: forming an initial graphenic-based membrane on a growth substrate; removing the initial graphenic-based membrane from the growth substrate; and positioning the removed graphenic-based membrane on a support substrate.

According to another aspect, the producing a graphenic-based membrane further comprises performing a conditioning treatment on the initial graphenic-based membrane while the initial graphenic-based membrane is on the growth substrate.

According to another aspect, the performing a conditioning treatment comprises an ion beam treatment of the initial graphenic-based membrane.

According to another aspect, the irradiating the region of the graphenic-based membrane with charged particles is performed after performing the conditioning treatment.

According to another aspect, the conditioning treatment is a treatment selected from the group consisting of a thermal treatment, a UV-oxygen treatment, and ion beam treatment, or combinations thereof.

According to another aspect, the forming an initial graphenic-based membrane comprises a chemical vapor deposition technique.

According to another aspect, the irradiating the region of the graphenic-based membrane with charged particles is performed while the removed graphenic-based membrane is on the support substrate.

According to another aspect, the charged particles comprise a noble gas, Ga, Au, Bi, or C60.

According to another aspect, the charged particles comprise helium.

According to another aspect, the carbonaceous material comprises amorphous carbon.

According to another aspect, the carbonaceous material is a material selected from the group consisting of amorphous carbon, one or more hydrocarbons, oxygen containing carbon compounds, nitrogen containing carbon compounds, or any combination thereof.

According to another aspect, the graphenic-based membrane comprises multilayer graphene material.

According to another aspect, the multilayer graphene material comprises between about 10 and 20 graphene material layers.

According to another embodiment there is provided a method of forming a membrane. The method comprises: producing a graphenic-based membrane having one or more layers of graphenic-based material; identifying a region of the graphenic-based membrane having intrinsic or native defects; irradiating the identified region of the graphenic-based membrane with charged particles while introducing carbonaceous material on a surface of the one or more layers of graphenic-based material to heal the intrinsic or native defects.

According to another aspect, the graphenic-based membrane is a graphene-based membrane.

According to another embodiment there is provided a method of forming a membrane. The method comprises: producing a graphenic-based membrane having one or more layers of graphenic-based material, and carbonaceous material on a surface of the one or more layers of graphenic-based material; identifying a region of the graphenic-based membrane having intrinsic or native defects; irradiating the identified region of the graphenic-based membrane with charged particles to heal the intrinsic or native defects.

According to another embodiment there is provided a method of forming a membrane. The method comprises: producing a graphenic-based membrane having one or more layers of graphenic-based material the graphenic-based membrane having intrinsic or native defects in a region, and having a plurality of selectively introduced perforations in addition to the intrinsic or native defects; and irradiating the region of the graphenic-based membrane with charged particles while introducing carbonaceous material on a surface of the one or more layers of graphenic-based material to heal the intrinsic or native defects.

According to one aspect, the graphenic-based membrane is a graphene-based membrane.

According to another embodiment there is provided a method of forming a membrane. The method comprises: producing a graphenic-based membrane having one or more layers of graphenic-based material, and carbonaceous material on a surface of the one or more layers of graphenic-based material, the graphenic-based membrane having intrinsic or native defects in a region, and having a plurality of selectively introduced perforations in addition to the intrinsic or native defects; and irradiating the region of the graphenic-based membrane with charged particles to heal the intrinsic or native defects.

According to another aspect, the graphenic-based membrane is a graphene-based membrane.

According to another aspect, the selectively introduced perforations have a first characteristic size, and the region includes intrinsic or native defects of a second characteristic size larger than the first characteristic size.

According to another aspect, the irradiating the region of the graphenic-based membrane with charged particles comprises: identifying the region based on the intrinsic or native defects of a second characteristic size larger than the first characteristic size; and scanning a charged particle beam over the identified region.

According to another embodiment there is provided a method of forming a membrane. The method comprises: forming a graphenic-based membrane on a growth substrate, the graphenic-based membrane having one or more layers of graphenic-based material; performing a conditioning treatment comprises an ion beam treatment on the graphenic-based membrane while the graphenic-based membrane is on the growth substrate; and irradiating the region of the graphenic-based membrane with charged particles while introducing carbonaceous material on a surface of the one or more layers of graphenic-based material to heal the intrinsic or native defects, wherein the irradiating the region of the graphenic-based membrane with charged particles is performed after performing the conditioning treatment.

According to another aspect, the graphenic-based membrane is a graphene-based membrane.

According to another embodiment there is provided a method of forming a membrane. The method comprises: forming a graphenic-based membrane on a growth substrate, the graphenic-based membrane having one or more layers of graphenic-based material, and carbonaceous material on a surface of the one or more layers of graphenic-based material; performing a conditioning treatment comprises an ion beam treatment on the graphenic-based membrane while the graphenic-based membrane is on the growth substrate; and irradiating the region of the graphenic-based membrane with charged particles to heal the intrinsic or native defects, wherein the irradiating the region of the graphenic-based membrane with charged particles is performed after performing the conditioning treatment.

According to another aspect, the graphenic-based membrane is a graphene-based membrane.

### BRIEF DESCRIPTION OF THE DRAWINGS

FIG. 1 is a flow chart illustrating a method of forming a graphenic-based membrane according to inventive concepts disclosed herein.

FIG. 2 is a scanning transmission electron microscopy (STEM) micrograph of a graphene-based material before charged particle irradiation at a level for healing according to inventive concepts disclosed herein.

FIG. 3 is a magnified image of the STEM micrograph of FIG. 2 with arrows pointing to some identified defects.

FIG. 4 is a STEM micrograph of the region shown in FIG. 3 after charged particle irradiation for healing.

FIG. 5 is a STEM micrograph of another region of the graphene-based material shown in FIG. 2 before charged particle irradiation at a level for healing.

FIG. 6 is a STEM micrograph of the region shown in FIG. 5 after charged particle irradiation for healing.

### DETAILED DESCRIPTION

Various aspects of the subject technology provide methods and systems for healing intrinsic or native defects, such as tears, of a graphenic-based membrane, such as a graphene-based membrane or a graphitic-based membrane.

The intrinsic or native defects in the graphenic-based membrane, in particular those of a larger size such as some tears, may adversely affect the integrity of the membrane, or may reduce its function as a filter when the graphenic-based membrane has selectively introduced perforations. In particular, when the intrinsic or native defects are of a larger size than the selectively introduced pores, the graphenic-based membrane may allow a species of a larger size to pass through the intrinsic or native defects, where the species of a larger size is intended to be restricted from passing through the membrane. On the other hand, intrinsic or native defects below a critical size required for application-specific separation may be useful from a permeability perspective, as long as such defects do not negatively impact the integrity of the membrane.

According to certain inventive concepts disclosed herein, the region of the graphenic-based membrane where the intrinsic or native defects exist may be first identified. In other embodiments the region of the graphenic-based membrane where the intrinsic or native defects exist need not be identified prior to the healing process. If a region is to be identified, the identified region is then irradiated with charged particles of an appropriate flux, fluence and energy to heal the intrinsic or native defect in the region, thus increasing the integrity, and in certain embodiments, maintaining the filter function of the graphenic-based membrane.

### Forming Graphenic-Based Membrane

The membrane according to embodiments may be, for example, a graphenic-based membrane, such as a graphene-based membrane or a graphitic-based membrane, formed according to various methods, as described below. Once the membrane is formed as described for example in this section on forming a graphenic-based membrane, the membrane may be subject to a healing process as described later in the section on healing.

In an embodiment, the membrane may be a macroscale sheet suitable for formation of perforations through exposure of the sheet to electrons or ions. In a further embodiment, the macroscale sheet may be suitable for formation of perforations through exposure of the sheet to ultraviolet light and an oxygen containing gas such as air. The perforated sheets described herein have a variety of applications including, but not limited to, filtration applications. Suspended macroscale sheets and methods for making macroscale sheets comprising single layer or multilayer graphene are also described herein.

In embodiments, the sheet of graphene-based material comprises a sheet of single layer graphene, multilayer graphene, or a combination thereof. In an embodiment, the sheet of graphene-based material may be formed by chemical vapor deposition (CVD) followed by at least one additional conditioning or treatment step. In embodiments, the conditioning step may be selected from thermal treatment, UV-oxygen treatment, ion beam treatment, or combinations thereof. The treated sheet may include reduced graphene oxide membranes and carbon nanomembranes (CNM). Carbon nanomembranes are typically generated from crosslinked aromatic self-assembled monolayers and can be approximately 1 nm thick (M. Ai and A. Golzhauser, Beilstein Bozen Symposium on Molecular Engineering and Control May 14th-18th, 2012, Prien (Chiemsee), Germany). These Carbon nanomembranes (CNM) are appropriate for being perforated. Further embodiments include combinations of these Carbon nanomembranes with graphene, such as graphene/CNM, CNM/graphene, and graphene/CNM/graphene.

In an embodiment, thermal treatment may include heating to a temperature from 200° C. to 800° C. at a pressure of 10⁻⁷ Torr to atmospheric pressure for a time of 2 hours to 8 hours. In an embodiment, UV-ozone treatment involves exposure to light from 150 nm to 300 nm and an intensity from 10 to 100 mW/cm² or 100 to 1000 mW/cm² at from 1 mm to 50 mm distance for a time from 60 to 600 seconds. In embodiments, UV-oxygen treatment may be performed at room temperature or at a temperature greater than room temperature. In further embodiments, UV-oxygen treatment may be performed at atmospheric pressure (e.g. 1 atm) or under vacuum. In an embodiment, ion beam treatment may involve exposure of the graphene-based material to ions having an ion energy from 50 eV to 1000 eV (for pretreatment) and the fluence is from 3×10¹⁰ ions/cm² to 8×10¹¹ ions/cm² or 3×10¹⁰ ions/cm² to 8×10¹³ ions/cm² (for pretreatment). In a further embodiment, the source of ions is collimated, such as a broad beam or flood source. In an embodiment, the ions may be noble gas ions such as Xe. In an embodiment, one or more conditioning steps may be performed while the graphene-based material is attached to a substrate, such as a growth substrate.

In an embodiment, the sheet of graphene-based material following chemical vapor deposition comprises multilayer graphene having at least two surfaces and carbonaceous material provided on said surfaces of the multilayer graphene. In embodiments, the carbonaceous material may be located on one of the two surfaces or on both. In a further embodiment, additional graphenic carbon may also be present on the surface(s) of the multilayer graphene.

In an embodiment, the graphene-based material is not perforated after the conditioning step(s). In an embodiment the conditioning/treatment process does not substantially affect the domain size or extent of defects in the material. As examples, said multilayer graphene before or after conditioning treatment may be characterized by an average size domain for long range order greater than or equal to 1 micrometer, long range lattice periodicity on the order of 1 micrometer and/or has an extent of disorder characterized by less than 1% content of lattice defects. The domains may have a size in the range from 30 micrometers to 3 millimeters, or from 100 micrometers to 1 centimeter for example. In other embodiments the conditioning/treatment process may heal some of the defects so as to reduce the number of defects in the material.

In an embodiment, the carbonaceous material may further comprise non-carbon elements. In an embodiment, said non-carbon elements may be selected from the group consisting of hydrogen, oxygen, silicon, copper, iron, aluminum, magnesium, calcium, boron, and nitrogen and combinations thereof. In an embodiment, aluminum, magnesium, calcium, boron, and nitrogen may be present only in trace amounts. In an embodiment, the carbonaceous material may have an elemental composition comprising carbon, hydrogen and oxygen. In a further embodiment, the carbonaceous material may have a molecular composition comprising amorphous carbon, one or more hydrocarbons, oxygen containing carbon compounds, nitrogen containing carbon compounds or any combination of these. In a further embodiment, the non-carbon element, such as boron or silicon substitutes for carbon in the lattice. In an embodiment the carbonaceous material may not exhibit long range order. In an embodiment, the carbonaceous material may be in physical contact with at least one of said surfaces of the multilayer graphene. In an embodiment, the characteristics of the carbonaceous carbon material are those as determined after at least one conditioning process.

Also provided herein are sheets of graphene-based material suspended over a supporting structure. In various embodiments, CVD graphene or graphene-based material can be liberated from its growth substrate (e.g., Cu) and transferred to a supporting grid, mesh or other porous supporting structure. In embodiments, the porous supporting structure may be polymeric, metallic or ceramic. In an embodiment, the supporting structure may be configured so that at least some portions of the sheet of graphene-based material are suspended from the supporting structure. For example, at least some portions of the sheet of graphene-based material are not in contact with the supporting structure. In an embodiment, the suspended area may be greater than 10 nm and less than 10 micrometers. In an embodiment, a sheet of graphene-based material comprising: multilayer graphene having at least two surfaces; and a carbonaceous material provided on said multilayer layer graphene; wherein exposure of said sheet of graphene-based material to ions characterized by an ion energy ranging from 10 eV to 100 keV and a fluence ranging from 1×10¹³ ions/cm² to 1×10²¹ ions/cm² produces perforations in the sheet of graphene-based material. In a further embodiment, at least a portion of the single layer graphene may be suspended. In yet a further embodiment, a mask or template is not present between the source of ions and the sheet of graphene-based material. In a further embodiment, the source of ions may be collimated, such as a broad beam or flood source. In embodiments the ions are noble gas ions, and are selected from the group consisting of Xe+, Ne+, or Ar+, or are He+ ions.

In an embodiment, the ions may be selected from the group consisting of Xe+, Ne+, or Ar+, the ion energy ranges from 5 eV to 50 eV and the ion dose ranges from 5×10¹⁴ ions/cm² to 5×10¹⁵ ions/cm². In an embodiment, the ion energy ranges from 1 keV to 40 keV and the ion dose ranges from 1×10¹⁹ ions/cm² to 1×10²¹ ions/cm². These parameters can be used for He ions. In a further embodiment, a background gas may be present during ion irradiation. For example, the sheet of graphene-based material may be exposed to the ions in an environment comprising partial pressure of 5×10⁻⁴ Torr to 5×10⁻⁵ Torr of oxygen, nitrogen or carbon dioxide at a total pressure of 10⁻³ Torr to 10⁻⁵ Torr. In yet a further embodiment the ion irradiation conditions when a background gas is present include an ion energy ranging from 100 eV to 1000 eV and an ion dose ranging from 1×10¹³ ions/cm² to 1×10¹⁴ ions/cm². A quasi-neutral plasma may be used under these conditions.

In an aspect, the macroscale sheet of graphene-based material may be suitable for formation of perforations over greater than 10% or greater or 15% or greater of said area of said sheet of graphene-based material. In combination, at least one lateral dimension of the sheet may be from 10 nm to 10 cm, or greater than 1 mm to less than or equal to 10 cm, or lateral dimensions as described herein. In an embodiment, the mean of the pore size may be from 0.3 nm to 1 μm. In embodiments, the coefficient of variation of the pore size may be from 0.1 to 2. In an embodiment, a perforated (hole) area correspond to 0.1% or greater of said area of said sheet of graphene-based material. In a further embodiment, the perforations may be characterized by an average area of said perforations selected from the range of 0.2 nm² to 0.25 μm².

Graphene represents a form of carbon in which the carbon atoms reside within a single atomically thin sheet or a few layered sheets (e.g., about 20 or less) of fused six-membered rings forming an extended sp²-hybridized carbon planar lattice. Graphene-based materials include, but are not limited to, single layer graphene, multilayer graphene or interconnected single or multilayer graphene domains and combinations thereof. In an embodiment, graphene-based materials also include materials which have been formed by stacking single or multilayer graphene sheets. In embodiments, multilayer graphene includes 2 to 20 layers, 2 to 10 layers or 2 to 5 layers. In an embodiment, layers of multilayered graphene may be stacked, but are less ordered in the z direction (perpendicular to the basal plane) than a thin graphite crystal.

In an embodiment, the membrane may be a sheet of graphene-based material which is a sheet of single or multilayer graphene or a sheet comprising a plurality of interconnected single or multilayer graphene domains, which may be observed in any known manner such as using for example small angle electron diffraction, transmission electron microscopy, etc. In embodiments, the multilayer graphene domains have 2 to 5 layers or 2 to 10 layers. As used herein, a “domain” refers to a region of a material where atoms are uniformly ordered into a crystal lattice. A domain is uniform within its boundaries, but different from a neighboring region. For example, a single crystalline material has a single domain of ordered atoms. In an embodiment, at least some of the graphene domains may be nanocrystals, having domain size from 1 to 100 nm or 10-100 nm. In an embodiment, at least some of the graphene domains have a domain size greater than 100 nm to 1 micron, or from 200 nm to 800 nm, or from 300 nm to 500 nm. In an embodiment, a domain of multilayer graphene may overlap a neighboring domain. “Grain boundaries” formed by crystallographic defects at edges of each domain differentiate between neighboring crystal lattices. In some embodiments, a first crystal lattice may be rotated relative to a second crystal lattice, by rotation about an axis perpendicular to the plane of a sheet, such that the two lattices differ in “crystal lattice orientation.”

In an embodiment, the membrane may be a sheet of graphene-based material comprising a sheet of single or multilayer graphene or a combination thereof. In an embodiment, the sheet of graphene-based material may be a sheet of single or multilayer graphene or a combination thereof In another embodiment, the sheet of graphene-based material may be a sheet comprising a plurality of interconnected single or multilayer graphene domains. In an embodiment, the interconnected domains may be covalently bonded together to form the sheet. When the domains in a sheet differ in crystal lattice orientation, the sheet may be polycrystalline. In an embodiment the single layer graphene may be characterized by an average size domain for long range order greater than or equal to 1 μm. In a further embodiment the single layer graphene has an extent of disorder characterized as an average distance between crystallographic defects of 100 nm.

In embodiments, the thickness of the sheet of graphene-based material may be from 0.3 to 10 nm, 0.34 to 10 nm, from 0.34 to 5 nm, or from 0.34 to 3 nm. In an embodiment, the thickness includes both single layer graphene and the non-graphenic carbon.

In an embodiment, the membrane may be a sheet of graphene-based material comprising intrinsic or native defects. Intrinsic or native defects are those resulting from preparation of the graphene-based material in contrast to perforations which are selectively introduced into a sheet of graphene-based material or a sheet of graphene. Such intrinsic or native defects include, but are not limited to, lattice anomalies, pores, tears, cracks or wrinkles. Lattice anomalies can include, but are not limited to, carbon rings with other than 6 members (e.g. 5, 7 or 9 membered rings), vacancies, interstitial defects (including incorporation of non-carbon atoms in the lattice), and grain boundaries. As used herein, perforations do not include openings in the graphene lattice due to intrinsic or native defects or grain boundaries.

In embodiments, graphene may be the dominant material in a graphene-based material. For example, a graphene-based material comprises at least 20% graphene, 30% graphene, or at least 40% graphene, or at least 50% graphene, or at least 60% graphene, or at least 70% graphene, or at least 80% graphene, or at least 90% graphene, or at least 95% graphene. In embodiments, a graphene-based material comprises a range of graphene selected from 30% to 95%, or from 40% to 80% from 50% to 70%, from 60% to 95% or from 75% to 100%. The amount of graphene in the graphene-based material is measured as an atomic percentage utilizing known methods including transmission electron microscope examination and the like, measuring mechanical properties such as with an atomic force microscope, etc. In an embodiment, the amount of graphene in the graphene-based material is measured as an atomic percentage.

In an embodiment, the membrane may be a sheet of graphene-based material further comprises carbonaceous material located on at least one surface of the sheet of graphene-based material. In an embodiment, the sheet may be defined by two base surfaces (e.g. top and bottom faces of the sheet) and side faces. In a further embodiment, the “bottom” face of the sheet is that face which contacted the substrate during CVD growth of the sheet and the “free” face of the sheet opposite the “bottom” face. In an embodiment, carbonaceous carbon material may be located on one or both base surfaces of the sheet (e.g. the substrate side of the sheet and/or the free surface of the sheet). In a further embodiment, the sheet of graphene-based material includes a small amount of one or more other materials on the surface, such as, but not limited to, one or more dust particles or similar contaminants.

In an embodiment, the membrane may be a layer comprising the sheet of graphene-based material further comprising carbonaceous material located on the surface of the sheet of graphene-based material. In an embodiment, the carbonaceous material does not possess long range order and may be classified as amorphous. In embodiments, the carbonaceous material further comprises elements other than carbon and/or hydrocarbons. In an embodiment, non-carbon elements which may be incorporated in the carbonaceous material include hydrogen, oxygen, silicon, copper and iron. In further embodiment, the carbonaceous material comprises hydrocarbons. In embodiments, carbon may be the dominant material in carbonaceous carbon material.

Perforation techniques suitable for use in perforating the graphene-based materials described herein include ion-based perforation methods and UV-oxygen based methods.

Ion-based perforation methods include methods in which the graphene-based material is irradiated with a directional source of ions. In a further embodiment, the ion source may be collimated. In an embodiment the ion source may be a broad beam or flood source. A broad field or flood ion source can provide an ion flux which is significantly reduced compared to a focused ion beam. The ion source inducing perforation of the graphene or other two-dimensional material in embodiments of the present disclosure is considered to provide a broad ion field, also commonly referred to as an ion flood source. In an embodiment, the ion flood source does not include focusing lenses. In embodiments, the ion source may be operated at less than atmospheric pressure, such as at 10⁻³ to 10⁻⁵ Torr or 10⁻⁴ to 10⁻⁶ Torr. In an embodiment, the environment also contains background amounts (e.g. on the order of 10⁻⁵ Torr) of oxygen (O₂), nitrogen (N₂) or carbon dioxide (CO₂). In embodiments, the ion beam may be perpendicular to the surface of the layer(s) of the material (incidence angle of 0 degrees) or the incidence angle may be from 0 to 45 degrees, 0 to 20 degrees, 0 to 15 degrees or 0 to 10 degrees. In a further embodiment, exposure to ions does not include exposure to a plasma.

UV-oxygen based perforation methods include methods in which the graphene-based material is simultaneously exposed to ultraviolet (UV) light and an oxygen containing gas. Ozone may be generated by exposure of an oxygen containing gas such as oxygen or air to the UV light, in which case the graphene-based material is exposed to oxygen. Ozone may also be supplied by an ozone generator device. In an embodiment, the UV-ozone based perforation method further includes exposure of the graphene-based material to atomic oxygen. Suitable wavelengths of UV light include, but are not limited to wavelengths below 300 nm or from 150 nm to 300 nm. In embodiments, the intensity is from 10 to 100 mW/cm² at 6 mm distance or 100 to 1000 mW/cm² at 6 mm distance. For example, suitable light is emitted by mercury discharge lamps (e.g. about 185 nm and 254 nm). In embodiments, UV/ozone cleaning is performed at room temperature or at a temperature greater than room temperature. In further embodiments, UV/ozone cleaning is performed at atmospheric pressure (e.g. 1 atm) or under vacuum.

Perforations are sized as described herein to provide desired selective permeability of a species (atom, molecule, protein, virus, cell, etc.) for a given application. Selective permeability relates to the propensity of a porous material or a perforated two-dimensional material to allow passage (or transport) of one or more species more readily or faster than other species. Selective permeability allows separation of species which exhibit different passage or transport rates. In two-dimensional materials selective permeability correlates to the dimension or size (e.g., diameter) of apertures and the relative effective size of the species. Selective permeability of the perforations in two-dimensional materials such as graphene-based materials can also depend on functionalization of perforations (if any) and the specific species that are to be separated. Separation of two or more species in a mixture includes a change in the ratio(s) (weight or molar ratio) of the two or more species in the mixture after passage of the mixture through a perforated two-dimensional material.

In embodiments, the characteristic size of the perforation may be from 0.3 to 10 nm, from 1 to 10 nm, from 5 to 10 nm, from 5 to 20 nm, from 10 nm to 50 nm, from 50 nm to 100 nm, from 50 nm to 150 nm, from 100 nm to 200 nm, or from 100 nm to 500 nm. In an embodiment, the average pore size is within the specified range. In embodiments, 70% to 99%, 80% to 99%, 85% to 99% or 90 to 99% of the perforations in a sheet or layer fall within a specified range, but other pores fall outside the specified range.

Nanomaterials in which pores are intentionally created may be referred to herein as “perforated graphene,” “perforated graphene-based materials” or “perforated two-dimensional materials, and the like.” Perforated graphene-based materials include materials in which non-carbon atoms have been incorporated at the edges of the pores. Pore features and other material features may be characterized in a variety of manners including in relation to size, area, domains, periodicity, coefficient of variation, etc. For instance, the size of a pore may be assessed through quantitative image analysis utilizing images preferentially obtained through transmission electron microscopy, and if TEM is ineffective, through atomic force microscopy, and if AFM is ineffective, through scanning electron microscopy. The boundary of the presence and absence of material identifies the contour of a pore. The size of a pore may be determined by shape fitting of an expected species against the imaged pore contour where the size measurement is characterized by smallest dimension unless otherwise specified. For example, in some instances, the shape may be round or oval. The round shape exhibits a constant and smallest dimension equal to its diameter. The width of an oval is its smallest dimension. The diameter and width measurements of the shape fitting in these instances provide the size measurement, unless specified otherwise.

Each pore size of a test sample may be measured to determine a distribution of pore sizes within the test sample. Other parameters may also be measured such as area, domain, periodicity, coefficient of variation, etc. Multiple test samples may be taken of a larger membrane to determine that the consistency of the results properly characterizes the whole membrane. In such instance, the results may be confirmed by testing the performance of the membrane with test species. For example, if measurements indicate that certain sizes of species should be restrained across the membrane, a performance test provides verification with test species. Alternatively, the performance test may be utilized as an indicator that the pore measurements will determine a concordant pore size, area, domains, periodicity, coefficient of variation, etc.

In some embodiments, the perforations are characterized by a distribution of pores with a dispersion characterized by a coefficient of variation of 0.1 to 2. The size distribution of holes may be narrow, e.g., limited to a coefficient of variation less than 2. In some embodiments involving circular shape fitting, the equivalent diameter of each pore is calculated from the equation A=π d²/4. Otherwise, the area is a function of the shape fitting. When the pore area is plotted as a function of equivalent pore diameter, a pore size distribution may be obtained. The coefficient of variation of the pore size may be calculated herein as the ratio of the standard deviation of the pore size to the mean of the pore size as measured across the test samples. The average area of perforations is an averaged measured area of the pores as measured across the test samples.

In some embodiments, the ratio of the area of the perforations to the ratio of the area of the sheet may be used to characterize the sheet as a density of perforations. The area of a test sample may be taken as the planar area spanned by the test sample. Additional sheet surface area may be excluded due to wrinkles other non-planar features. Characterization may be based on the ratio of the area of the perforations to the test sample area as density of perforations excluding features such as surface debris. Characterization may be based on the ratio of the area of the perforations to the suspended area of the sheet. As with other testing, multiple test samples may be taken to confirm consistency across tests and verification may be obtained by performance testing. The density of perforations may be, for example, 2 per nm² (2/nm²) to 1 per μm² (1/μm²).

In an embodiment, the ratio of the area of the perforations to the ratio of the area of the sheet may be used to characterize the sheet. The area of the perforations may be measured using quantitative image analysis. The area of the sheet may be taken as the planar area spanned by the sheet if it is desired to exclude the additional sheet surface area due to wrinkles or other non-planar features of the sheet. In a further embodiment, characterization may be based on the ratio of the area of the perforations to the sheet area excluding features such as surface debris. In an additional embodiment, characterization may be based on the ratio of the area of the perforations to the suspended area of the sheet.

In embodiments, the perforated area comprises 0.1% or greater, 1% or greater or 5% or greater of the sheet area, less than 10% of the sheet area, less than 15% of the sheet area, from 0.1% to 15% of the sheet area, from 1% to 15% of the sheet area, from 5% to 15% of the sheet area or from 1% to 10% of the sheet area. In a further embodiment, the perforations may be located over greater than 10% or greater than 15% of said area of said sheet of graphene-based material. As used herein, a macroscale sheet is macroscopic and observable by the naked eye. In embodiments, at least one lateral dimension of the sheet is greater than 1 cm, greater than 1 mm or greater than 5 mm. For example, the sheet has a lateral dimension greater than about 1 micrometer. In an additional embodiment, the lateral dimension of the sheet may be less than 10 cm. In an embodiment, the sheet has a lateral dimension greater than 1 mm and less than 10 cm. As used herein, a lateral dimension is perpendicular to the thickness of the sheet.

Chemical vapor deposition growth of graphene-based material typically involves use of a carbon containing precursor material, such as methane and a growth substrate. In an embodiment, the growth substrate is a metal growth substrate. In an embodiment, the metal growth substrate is a substantially continuous layer of metal rather than a grid or mesh. Metal growth substrates compatible with growth of graphene and graphene-based materials include transition metals and their alloys. In embodiments, the metal growth substrate is copper based or nickel based. In embodiments, the metal growth substrate is copper or nickel. In embodiments, the graphene-based material is removed from the growth substrate by dissolution of the growth substrate.

### Healing Process

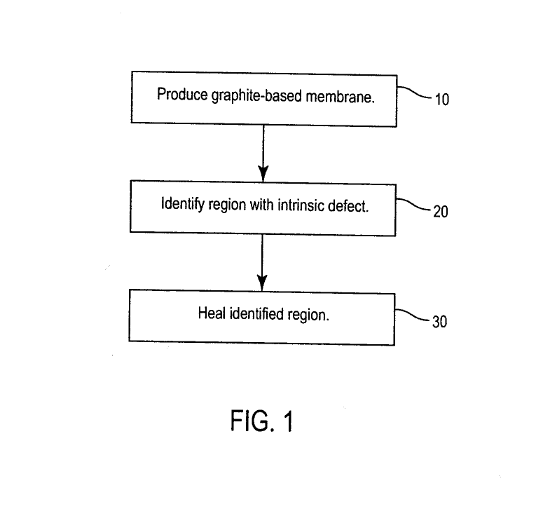

FIG. 1 illustrates a method of forming a graphenic-based membrane, including a particle irradiation healing process, according to inventive concepts disclosed herein.

In step 10, a graphenic-based membrane is produced, such as, for example, by the techniques described above. The graphenic-based membrane may be a graphene-based membrane. For example, the graphenic-based membrane may be produced as follows. An initial graphenic-based membrane is formed on a growth substrate, by a method such as chemical vapor deposition (CVD), for example. In the case that the graphenic-based membrane is a thin graphitic membrane, the thin graphitic membrane may be formed by, for example, electrostatic deposition, or a casting method, In the casting method, graphite is exfoliated and put into suspension, such as by using a modified hummers method. The suspension is then deposited on a substrate surface by drop casting, or if the substrate is porous, by vacuum deposited. Thin graphitic membranes may also be made by carbon nanomembranes (CNM) which are formed from a deposited and crosslinked layers of polycyclic aromatic hydrocarbons (PAHs), such as phenol compounds, for example.

The initial graphenic-based membrane is removed from the growth substrate, and the removed graphenic-based membrane may be positioned on a support substrate.

The initial graphenic-based membrane may be subject to a conditioning treatment, for example, while the initial graphenic-based membrane is on the growth substrate. The conditioning treatment may comprise a thermal treatment, a UV-oxygen treatment, or ion beam treatment, or combinations of these treatments. A plurality of selectively introduced perforations may also be formed in the initial graphenic-based membrane in the case the graphenic-based membrane is intended to function as filter, for example.

In general, the graphenic-based membrane produced in step 10 has one or more layers of graphenic-based material, and further has carbonaceous material on a surface of the one or more layers of graphenic-based material. For example, if the graphenic-based membrane is a graphene-based membrane, the layers may be layers of graphene. The graphenic-based membrane further has intrinsic or native defects.

In step 20, a region where the intrinsic or native defects exist, and are to be healed, is identified. The region may be identified according to the size of the intrinsic or native defects which exists. For example, the region may be identified only if the size of the intrinsic or native defects is above a characteristic defect size. The existence of intrinsic or native defects may be identified by methods such as measuring the electrical conductivity of the membrane, or detecting secondary electrons emitted when irradiating the membrane with primary electrons, such as during a scanning transmission electron micrograph scan. When scanning an ion beam over the membrane, defects can be detected as dark regions, which are areas where the secondary electron yield is low or non-existent, indicating that there is no material there. Methods for detecting the existence of intrinsic or native defects include Raman spectroscopy; residual gas analysis on particles being removed from the material; detecting back scattered radiation or particles; detecting Auger electrons; performing scanning probe microscopy; performing scanning tunneling microscopy; performing atomic force microscopy; performing X-ray spectroscopy; performing transmission electron microscopy; detecting nanoparticles on one or more microbalances or Faraday cups positioned behind the material.

In the case that the graphenic-based membrane comprises a plurality of selectively introduced perforations in addition to the intrinsic or native defects, the region may be identified only if the intrinsic or native defects are larger than the selectively introduced perforations. For example, the selectively introduced perforations may have a first characteristic size, and the region for healing may be identified only when intrinsic or native defects of a second characteristic size larger than the first characteristic size are present. The first characteristic size may be the equivalent diameter of the selectively introduced perforations, and the second characteristic size may be the equivalent diameter of intrinsic or native defects. Alternatively, the first characteristic size may be the minimum dimension (minor axis) of the selectively introduced perforations, and the second characteristic size may be the minimum dimension of intrinsic or native defects.

In step 30, the identified region is subject to an intrinsic or native defect healing process. For example, the identified region may be irradiated with charged particles to heal the intrinsic or native defects. The healing process may include irradiating the identified region of the graphenic-based membrane with charged particles having an ion energy ranging from 50 eV to 1000 eV, or 50 eV to 40 keV and the fluence may be from 3×10¹⁰ ions/cm² to 8×10¹¹ ions/cm², 3×10¹⁰ ions/cm² to 8×10¹³ ions/cm², or 3×10¹⁰ ions/cm² to 1×10¹⁹ ions/cm². The flux may be from 10¹⁰ ions/cm²/s to 10¹⁴ ions/cm²/s, or from 10¹⁰ ions/cm²/s to 10¹⁷ ions/cm²/s. The irradiation may include irradiating with a broad beam or a flood source, for example. The irradiation is done in the presence of carbonaceous material so that mobile carbonaceous surface contamination is present.

The graphenic-based membrane produced in step 10 may have carbonaceous material on a surface of the stacked layers of the graphenic-based membrane. The carbonaceous material may be a material such as amorphous carbon, one or more hydrocarbons, oxygen containing carbon compounds, nitrogen containing carbon compounds, or combination thereof. While not being restricted to any particular theory for the mechanism for healing, the healing may be facilitated by presence of the carbonaceous material. The charged particle irradiation may provide sufficient energy for the carbonaceous material to mobilize carbon atoms which migrate and/or move to the intrinsic or native defect regions of the graphitic material in the graphenic-based membrane, where the mobilized carbon form sp² bonds with graphitic material at the intrinsic or native defect. Thus, the intrinsic or native defect may be healed. The energy and the flux of the charged particles should be sufficient to mobilize the carbon of the carbonaceous material, but not so high as to damage the graphitic material in the graphenic-based membrane. At some energies the charged particle irradiation is milling (damaging) the graphenic-based membrane, but with sufficient carbon supply, the healing out competes the milling. The charged particle irradiation facilitates liberating the carbon from the carbonaceous material, such that it can be incorporated into the defected graphitic material.

According to an embodiment, the carbonaceous material need not initially be present in sufficient quantities on the surface of the graphenic-based membrane to allow for complete healing of the intrinsic or native defect. In this case, the carbonaceous material may be introduced to the surface of the graphenic-based membrane while the surface is irradiated with charged particles to heal the intrinsic or native defects. For example, carbon may be sputtered to the surface of the graphenic-based membrane while the surface is irradiated with charged particles. Alternatively, the graphenic-based membrane may be exposed to hydrocarbon gases while the surface is irradiated with charged particles, or the graphenic-based membrane may be exposed to carbon containing fluid at low enough temperature to be adsorbed on the membrane surface and the surface is then irradiated with charged particles. Furthermore, according to embodiments, the membrane may be heated while healing or afterwards, which further facilitates the healing.

### EXAMPLES

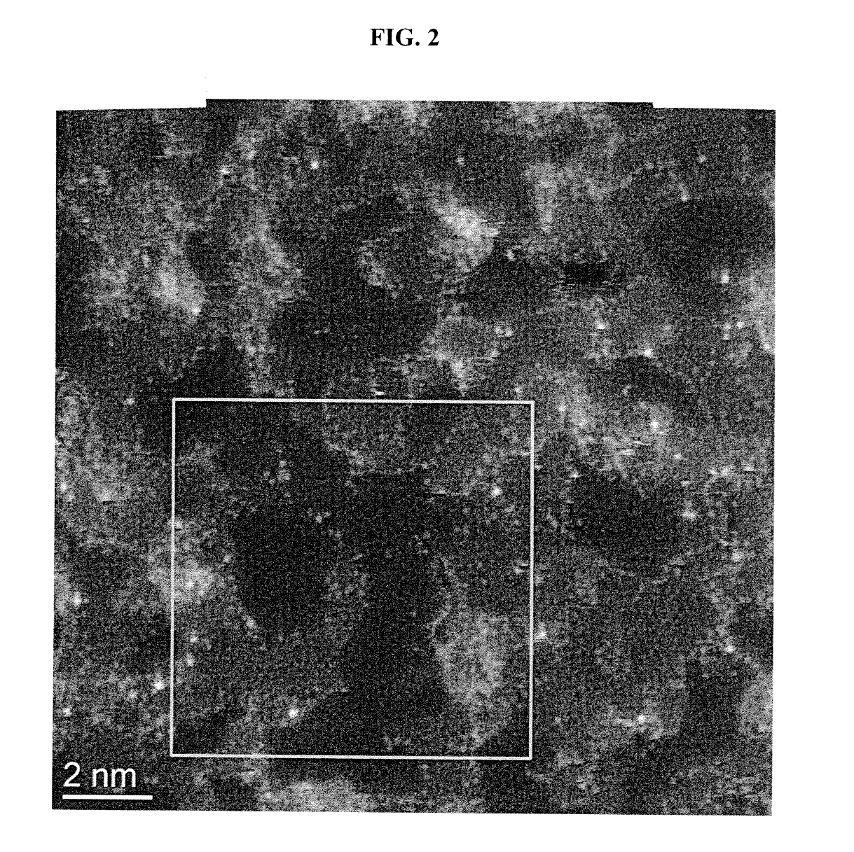

FIG. 2 is a scanning transmission electron microscopy (STEM) micrograph of a graphene-based material before intentional charged particle irradiation.

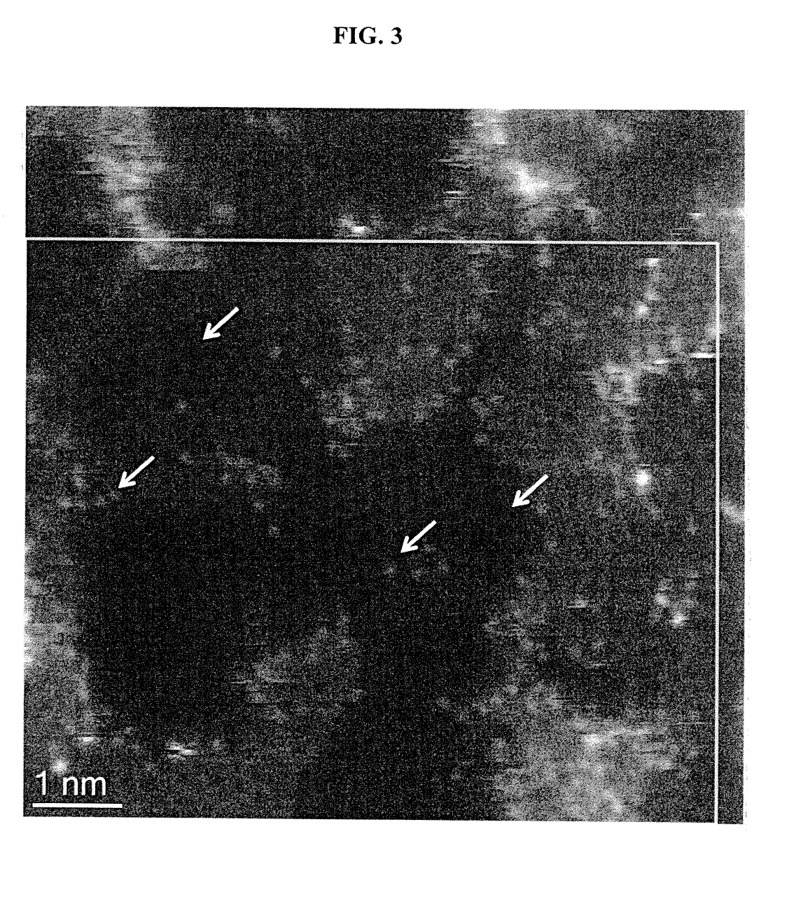

FIG. 3 is a magnified image of the STEM micrograph of FIG. 2 with arrows pointing to some identified defects. The brighter portions of the micrograph correspond to surface contamination on the graphene-based material, such as carbonaceous material. In FIG. 3, the graphene-based material has not yet been irradiated with charged particle irradiation at a level for healing, but only for taking the STEM micrograph. The box in FIG. 3 corresponds to the portion of the graphene-based material which will be subjected to charged particle irradiation for healing.

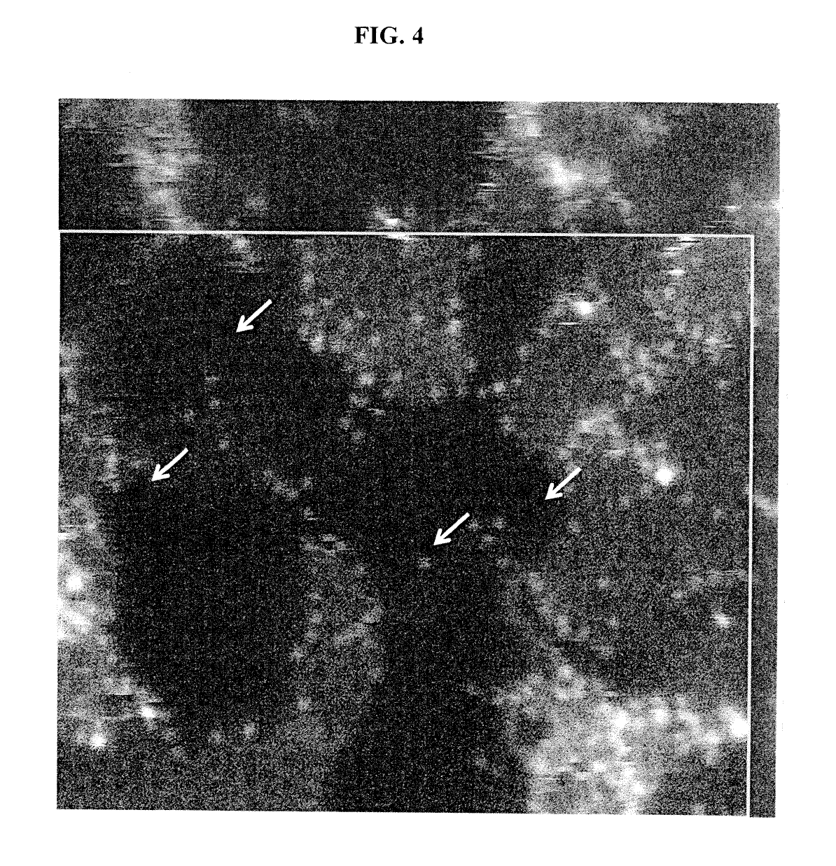

FIG. 4 is a STEM micrograph of the region shown in FIG. 3 after some charged particle irradiation for healing. In particular the region was scanned with a highly focused electron beam at 60 kV with a beam current of 40-60 pA and 1024 dwells per 8 nm. The defects indicated in FIG. 4 have changed relative to those in FIG. 3.

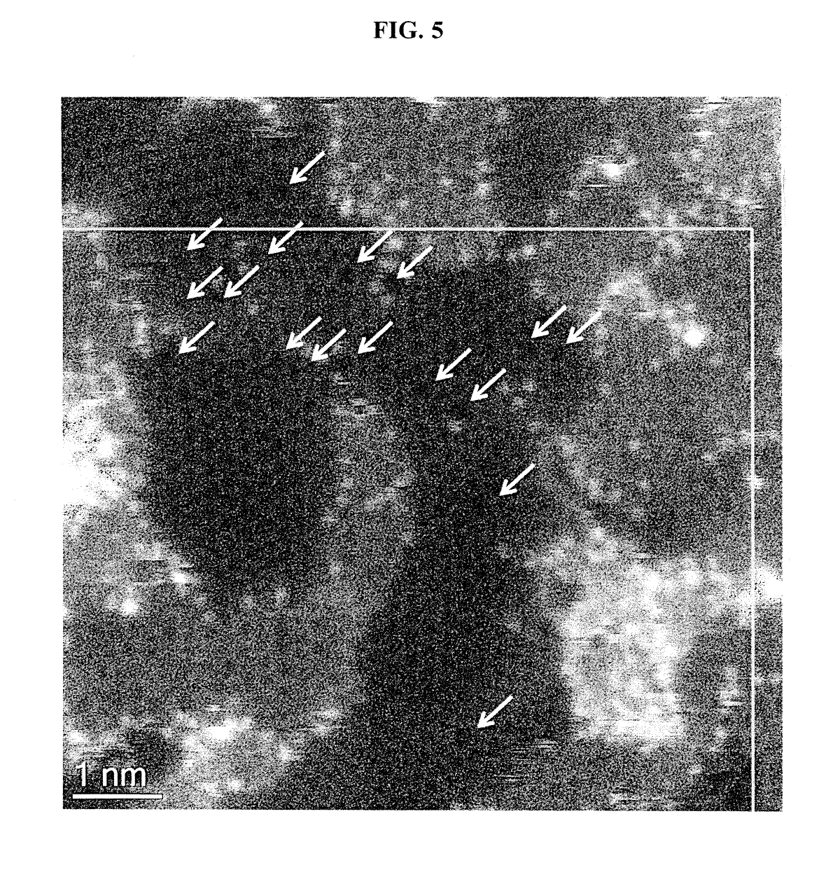

FIG. 5 is a STEM micrograph of another region of the graphene-based material shown in FIG. 2 before charged particle irradiation. Similar to FIG. 3, the box in FIG. 5 corresponds to the portion of the graphene-based material which will subjected to charged particle irradiation for healing, and the arrows point to identified defects.

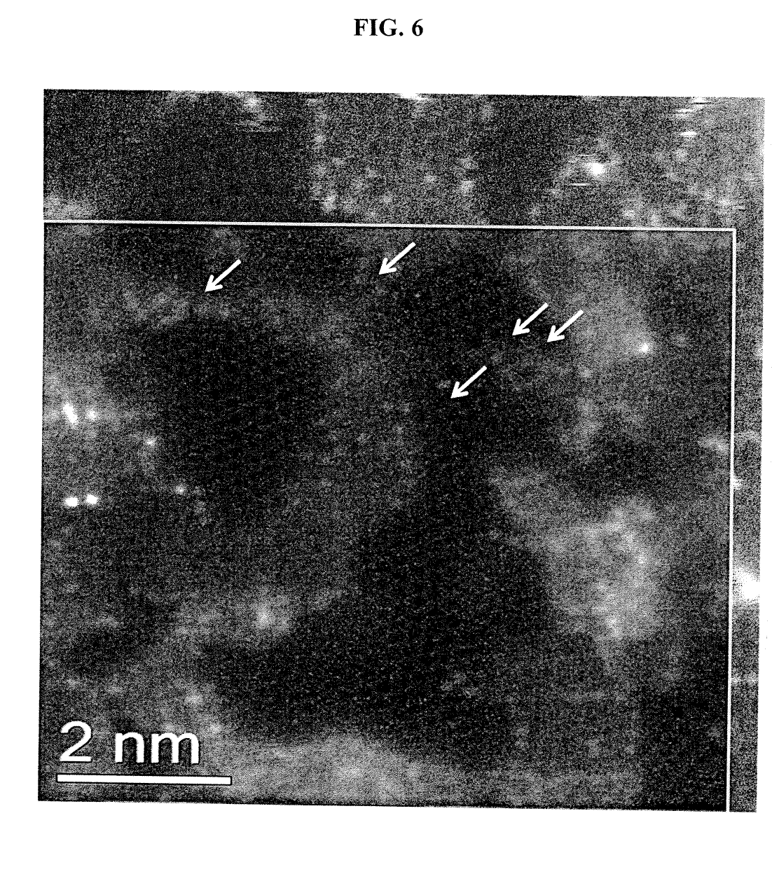

FIG. 6 is a STEM micrograph of the region shown in FIG. 5 after charged particle irradiation for healing in a similar manner to that shown for FIG. 4. As can be seen, the defects indicated in FIG. 6 have changed relative to those in FIG. 5. In particular, FIG. 6 illustrates a significantly lower number of defects in the portion irradiated.

The embodiments of the inventive concepts disclosed herein have been described in detail with particular reference to preferred embodiments thereof, but it will be understood by those skilled in the art that variations and modifications can be effected within the spirit and scope of the inventive concepts.

What is claimed is:

1. A method of forming a membrane, comprising:
forming a graphenic-based membrane on a growth substrate, the graphenic-based membrane having one or more layers of graphenic-based material;
removing the graphenic-based membrane from the growth substrate;
identifying a region of the graphenic-based membrane having intrinsic or native defects; and
irradiating the region of the graphenic-based membrane with charged particles while introducing carbonaceous material on a surface of the one or more layers of graphenic-based material to heal the intrinsic or native defects.

2. The method of claim 1, wherein the graphenic-based membrane is a graphene-based membrane.

3. A method of forming a membrane, comprising:
forming a graphenic-based membrane on a growth substrate, the graphenic-based membrane having one or more layers of graphenic-based material, and carbonaceous material on a surface of the one or more layers of graphenic-based material;
removing the graphenic-based membrane from the growth substrate;
identifying a region of the graphenic-based membrane having intrinsic or native defects; and
irradiating the region of the graphenic-based membrane with charged particles to heal the intrinsic or native defects.

4. The method of claim 3, wherein the graphenic-based membrane is a graphene-based membrane.

5. The method of claim 3, further comprising performing a conditioning treatment on the graphenic-based membrane while the graphenic-based membrane is on the growth substrate.

6. The method of claim 5, wherein the performing a conditioning treatment comprises an ion beam treatment of an initial graphenic-based membrane,

7. The method of claim 6, wherein the irradiating the region of the graphenic-based membrane with charged particles is performed after performing the conditioning treatment.

8. The method of claim 3, wherein the graphenic-based membrane comprises a plurality of selectively introduced perforations in addition to the intrinsic or native defects.

9. The method of claim 8, wherein the selectively introduced perforations have a first characteristic size, and the region includes intrinsic or native defects of a second characteristic size larger than the first characteristic size.

10. The method of claim 9, wherein the irradiating the region of the graphenic-based membrane with charged particles comprises:
identifying the region based on the intrinsic or native defects of a second characteristic size larger than the first characteristic size; and
scanning a charged particle beam over the identified region.

11. A method of forming a membrane, comprising:
producing a graphenic-based membrane having one or more layers of graphenic-based material, the graphenic-based membrane having intrinsic or native defects in a region; and
irradiating the region of the graphenic-based membrane with charged particles while introducing carbonaceous material on a surface of the one or more layers of graphenic-based material to heal the intrinsic or native defects.

12. The method of claim 11, wherein the graphenic-based membrane is a graphene-based membrane.

13. A method of forming a membrane, comprising:
producing a graphenic-based membrane having one or more layers of graphenic-based material, and carbonaceous material on a surface of the one or more layers of graphenic-based material, the graphenic-based membrane having intrinsic or native defects in a region; and
irradiating the region of the graphenic-based membrane with charged particles to heal the intrinsic or native defects.

14. The method of claim 13, wherein the intrinsic or native defects comprise at least one of lattice anomalies, pores, tears, cracks or wrinkles.

15. The method of claim 13, wherein the intrinsic or native defects comprise tears.

16. The method of claim 13, wherein the irradiating the region of the graphenic-based membrane comprises irradiating with charged particles having an ion energy ranging from 50 eV to 40 keV, and a flux ranging from 10¹⁰ ions/cm²/s to 10¹⁷ ions/cm²/s.

17. The method of claim 13, wherein the irradiating the region of the graphenic-based membrane comprises irradiating with one of a broad beam or a flood source.

18. The method of claim 13, wherein the producing a graphenic-based membrane comprises:
forming an initial graphenic-based membrane on a growth substrate;
removing the initial graphenic-based membrane from the growth substrate; and
positioning the removed graphenic-based membrane on a support substrate.

19. The method of claim 17, wherein the producing a graphenic-based membrane further comprises performing a conditioning treatment on the initial graphenic-based membrane while the initial graphenic-based membrane is on the growth substrate.

20. The method of claim 19, wherein the performing a conditioning treatment comprises an ion beam treatment of the initial graphenic-based membrane,

21. The method of claim 20, wherein the irradiating the region of the graphenic-based membrane with charged particles is performed after performing the conditioning treatment.

22. The method of claim 19, wherein the conditioning treatment is a treatment selected from the group consisting of a thermal treatment, a UV-oxygen treatment, and ion beam treatment, or combinations thereof.

23. The method of claim 18, wherein the forming an initial graphenic-based membrane comprises a chemical vapor deposition technique.

24. The method of claim 18, wherein the irradiating the region of the graphenic-based membrane with charged particles is performed while the removed graphenic-based membrane is on the support substrate.

25. The method of claim 13, wherein the charged particles comprise a noble gas. Ga, Au. Bi, or C60.

26. The method of claim 25, wherein the charged particles comprise helium.

27. The method of claim 13, wherein the carbonaceous material comprises amorphous carbon.

28. The method of claim 13, wherein the carbonaceous material is a material selected from the group consisting of amorphous carbon, one or more hydrocarbons, oxygen containing carbon compounds, nitrogen containing carbon compounds, or any combination thereof.

29. The method of claim 13, wherein the graphenic-based membrane comprises multilayer graphene material.

30. The method of claim 29, wherein the multilayer graphene material comprises between about 10 and 20 graphene material layers.

31. A method of forming a membrane, comprising:
producing a graphenic-based membrane having one or more layers of graphenic-based material;
identifying a region of the graphenic-based membrane having intrinsic or native defects;
irradiating the identified region of the graphenic-based membrane with charged particles while introducing carbonaceous material on a surface of the one or more layers of graphenic-based material to heal the intrinsic or native defects.

32. The method of claim 31, wherein the graphenic-based membrane is a graphene-based membrane.

33. A method of forming a membrane, comprising:
producing a graphenic-based membrane having one or more layers of graphenic-based material, and carbonaceous material on a surface of the one or more layers of graphenic-based material;
identifying a region of the graphenic-based membrane having intrinsic or native defects;
irradiating the identified region of the graphenic-based membrane with charged particles to heal the intrinsic or native defects.

34. A method of forming a membrane, comprising:
producing a graphenic-based membrane having one or more layers of graphenic-based material the graphenic-based membrane having intrinsic or native defects in a region, and having a plurality of selectively introduced perforations in addition to the intrinsic or native defects; and
irradiating the region of the graphenic-based membrane with charged particles while introducing carbonaceous material on a surface of the one or more layers of graphenic-based material to heal the intrinsic or native defects.

35. The method of claim 34, wherein the graphenic-based membrane is a graphene-based membrane.

36. A method of forming a membrane, comprising:
producing a graphenic-based membrane having one or more layers of graphenic-based material, and carbonaceous material on a surface of the one or more layers of graphenic-based material, the graphenic-based membrane having intrinsic or native defects in a region, and having a plurality of selectively introduced perforations in addition to the intrinsic or native defects; and
irradiating the region of the graphenic-based membrane with charged particles to heal the intrinsic or native defects.

37. The method of claim 36, wherein the graphenic-based membrane is a graphene-based membrane.

38. The method of claim 36, wherein the selectively introduced perforations have a first characteristic size, and the region includes intrinsic or native defects of a second characteristic size larger than the first characteristic size.

39. The method of claim 38, wherein the irradiating the region of the graphenic-based membrane with charged particles comprises:
identifying the region based on the intrinsic or native defects of a second characteristic size larger than the first characteristic size; and
scanning a charged particle beam over the identified region.

40. A method of forming a membrane, comprising:
forming a graphenic-based membrane on a growth substrate, the graphenic-based membrane having one or more layers of graphenic-based material;
performing a conditioning treatment comprises an ion beam treatment on the graphenic-based membrane while the graphenic-based membrane is on the growth substrate; and
irradiating the region of the graphenic-based membrane with charged particles while introducing carbonaceous material on a surface of the one or more layers of graphenic-based material to heal the intrinsic or native defects, wherein the irradiating the region of the graphenic-based membrane with charged particles is performed after performing the conditioning treatment.

41. The method of claim 40, wherein the graphenic-based membrane is a graphene-based membrane.

42. A method of forming a membrane, comprising:
forming a graphenic-based membrane on a growth substrate, the graphenic-based membrane having one or more layers of graphenic-based material, and carbonaceous material on a surface of the one or more layers of graphenic-based material;
performing a conditioning treatment comprises an ion beam treatment on the graphenic-based membrane while the graphenic-based membrane is on the growth substrate; and
irradiating the region of the graphenic-based membrane with charged particles to heal the intrinsic or native defects, wherein the irradiating the region of the graphenic-based membrane with charged particles is performed after performing the conditioning treatment.

43. The method of claim 42, wherein the graphenic-based membrane is a graphene-based membrane.
